(19) United States
(12) Patent Application Publication
(10) Pub. No.: US 2020/0409438 A1
(43) Pub. Date: Dec. 31, 2020

(54) APPARATUS, METHODS AND SYSTEMS FOR THERMALLY ISOLATED SIGNAL AND POWER TRANSMISSION

(71) Applicant: Micron Technology, Inc., Boise, ID (US)

(72) Inventor: Mark E. Tuttle, Meridian, ID (US)

(21) Appl. No.: 16/452,989

(22) Filed: Jun. 26, 2019

(51) Int. Cl. G06F 1/20; H01L 23/538; F16L 59/065

(52) U.S. Cl. CPC G06F 1/206; F16L 59/065; H01L 23/538

(57) ABSTRACT

An apparatus comprising a relatively high temperature electronic device, a relatively low temperature electronic device operably coupled to the relatively high temperature electronic device. The operable coupling comprises at least one of optical coupling, inductive coupling or capacitive coupling through at least one contained free space located between the electronic device and the other electronic device across one of air or a full or partial vacuum in a volume of the contained free space adjacent a path of the operable coupling. Related systems and methods are also disclosed.

### TECHNICAL FIELD

Embodiments disclosed herein relate to apparatus, methods and systems for thermally isolated signal and power transmission between electronic apparatus. More particularly, embodiments disclosed herein relate to apparatus, methods and systems for thermally isolating mutually communicating apparatus (e.g., electronic devices) having substantially different operating temperatures.

### BACKGROUND

The electronics industry has developed a number of different approaches to implement high speed processing, many of which involve operating processors at cryogenic temperatures, for example from about −50° C. (about 223K) down to below about −270° C. (below about 3K). Such low operating temperatures, however, pose issues for effective operation of the processors in communication with conventional memory (e.g., DRAM) and peripheral input and output devices (e.g., keyboards, displays, sensors), all of which generally operate at an ambient or near-ambient temperature between about 15° C. and about 25° C., and each of which devices generate a substantial amount of heat during normal operation. Operably coupling such ambient and near-ambient temperature-operating devices to cryogenic processors thus presents a significant problem in the form of what may be called “heat contamination” through conventional electrical conductors adverse to the maintenance of the processors at necessary cryogenic operating temperatures. Such heat contamination may compromise operation of cryogenic processors in terms of speed reduction and inducement of error.

In addition, computing systems may include primary cryogenic processors, such as Quantum processors operating at milliKelvin temperatures (below about −270° C., or about 3K), operably coupled to backup cryogenic processors operating at substantially higher cryogenic temperatures, on the order of about −196° C. (about 77K) to about −50° C. (about 223K). Such systems also present a two-fold heat contamination problem by the backup processors to the Quantum processors, as well as by ambient or near-ambient temperature operating devices to the backup processor.

Substantial practical implementation of cryogenic processing has been limited by the relatively low capacity of memory operating at cryogenic temperatures, as well as the difficulty of communicating between cryogenic processors and memory operating at ambient or near-ambient temperatures without compromising processor operation.

### BRIEF DESCRIPTION OF THE DRAWINGS

FIG. 1 is a schematic depiction of a conventional technique for operably coupling two electronic devices operable at significantly different temperatures;

FIG. 2 is a schematic depiction of another conventional technique for operably coupling two electronic devices operable at significantly different temperatures;

FIG. 3A is a schematic depiction of an embodiment of the disclosure for operably coupling two electronic devices operable at significantly different temperatures;

FIG. 3B is a schematic depiction of another embodiment of the disclosure for operably coupling two electronic devices operable at significantly different temperatures;

FIG. 3C is a schematic depiction of a further embodiment of the disclosure for operably coupling two electronic devices operable at significantly different temperatures;

FIG. 4A depicts a specific example of a system comprising a cryogenic processor operably coupled to room temperature memory according to the embodiment of FIG. 3A;

FIG. 4B depicts a specific example of a system comprising a cryogenic processor operably coupled to room temperature memory according to the embodiment of FIG. 3B;

FIG. 4C depicts a specific example of a system comprising a cryogenic processor operably coupled to room temperature memory according to the embodiment of FIG. 3C;

FIG. 5 is a schematic depiction of yet another embodiment of the disclosure for operably coupling two electronic devices operable at significantly different temperatures;

FIG. 6 is a schematic depiction of yet another embodiment of the disclosure for operably coupling two electronic devices operable at significantly different temperatures;

FIG. 7 is a schematic depiction of an embodiment of the disclosure for operably coupling two electronic devices in the form of cryogenic processors operable at significantly different cryogenic temperatures; and

FIG. 8 is a schematic depiction of an electronic system comprising at least one cryogenic processor operably coupled to a memory device and peripheral devices operable at ambient or near-ambient temperatures.

### DETAILED DESCRIPTION

The following description provides specific details, such as sizes, shapes, material compositions, and orientations in order to provide a thorough description of embodiments of the disclosure. However, a person of ordinary skill in the art would understand that the embodiments of the disclosure may be practiced without necessarily employing these specific details. Embodiments of the disclosure may be practiced in conjunction with conventional fabrication techniques employed in the industry. In addition, the disclosure provided herein does not form a complete description of all components, their operability and interoperability, for a multi-apparatus computing system or subsystem comprising at least two components operating at greatly differing temperatures. Only those method acts and structures necessary to understand and implement embodiments of the disclosure are described in detail below. Additional acts and structures to form and operate a multi-apparatus computing system or subsystem will be readily apparent to those of ordinary skill in the art.

Drawings presented herein are for illustrative purposes only, and are not meant to be actual views of any particular material, component, structure, device, or system. Variations from the shapes depicted in the drawings as a result, for example, of manufacturing techniques and/or tolerances, are to be expected. Thus, embodiments described herein are not to be construed as being limited to the particular shapes or regions as illustrated, but include deviations in shapes that result, for example, from manufacturing. For example, a region illustrated or described as box-shaped may have rough and/or nonlinear features, and a region illustrated or described as round may include some rough and/or linear features. Moreover, sharp angles between surfaces that are illustrated may be rounded, and vice versa. Thus, the regions illustrated in the figures are schematic in nature, and their shapes are not intended to illustrate the precise shape of a region and do not limit the scope of the present claims. The drawings are not necessarily to scale.

As used herein, the terms “comprising,” “including,” “containing,” “characterized by,” and grammatical equivalents thereof are inclusive or open-ended terms that do not exclude additional, unrecited elements or method acts, but also include the more restrictive terms “consisting of” and “consisting essentially of” and grammatical equivalents thereof.

As used herein, the terms “longitudinal,” “vertical,” “lateral,” and “horizontal” are in reference to a major plane of a substrate (e.g., base material, base structure, base construction, etc.) in or on which one or more structures and/or features are formed and are not necessarily defined by earth's gravitational field. A “lateral” or “horizontal” direction is a direction that is substantially parallel to the major plane of the substrate, while a “longitudinal” or “vertical” direction is a direction that is substantially perpendicular to the major plane of the substrate. The major plane of the substrate is defined by a surface of the substrate having a relatively large area compared to other surfaces of the substrate.

As used herein, spatially relative terms, such as “beneath,” “below,” “lower,” “bottom,” “above,” “over,” “upper,” “top,” “front,” “rear,” “left,” “right,” and the like, may be used for ease of description to describe one element's or feature's relationship to another element(s) or feature(s) as illustrated in the figures. Unless otherwise specified, the spatially relative terms are intended to encompass different orientations of the materials in addition to the orientation depicted in the figures. For example, if materials in the figures are inverted, elements described as “over” or “above” or “on” or “on top of” other elements or features would then be oriented “below” or “beneath” or “under” or “on bottom of” the other elements or features. Thus, the term “over” can encompass both an orientation of above and below, depending on the context in which the term is used, which will be evident to one of ordinary skill in the art. The materials may be otherwise oriented (e.g., rotated 90 degrees, inverted, flipped) and the spatially relative descriptors used herein interpreted accordingly.

As used herein, the singular forms “a,” “an,” and “the” are intended to include the plural forms as well, unless the context clearly indicates otherwise.

As used herein, the terms “configured” and “configuration” refer to a size, shape, material composition, orientation, and arrangement of one or more of at least one structure and at least one apparatus facilitating operation of one or more of the structure and the apparatus in a predetermined way.

As used herein, the term “substantially” in reference to a given parameter, property, or condition means and includes to a degree that one of ordinary skill in the art would understand that the given parameter, property, or condition is met with a degree of variance, such as within acceptable manufacturing tolerances. By way of example, depending on the particular parameter, property, or condition that is substantially met, the parameter, property, or condition may be at least 90.0% met, at least 95.0% met, at least 99.0% met, or even at least 99.9% met.

As used herein, the term “may” with respect to a material, structure, feature or method act indicates that such is contemplated for use in implementation of an embodiment of the disclosure and such term is used in preference to the more restrictive term “is” so as to avoid any implication that other, compatible materials, structures, features and methods usable in combination therewith should or must be excluded.

As used herein the term “Air” means and includes not only ambient air comprising Oxygen, Nitrogen and Carbon Dioxide, but also other gases and mixtures of gases, and specifically Nitrogen and noble gases (e.g., helium, neon, argon), and combinations of such gases.

As used herein, the term “inductive coupling” means and includes not only simple (i.e., non-resonant) inductive coupling, but also resonant inductive coupling.

As used herein, the term “capacitive coupling” means and includes not only simple (i.e., non-resonant) capacitive coupling, but also resonant capacitive coupling.

As used herein with respect to operating temperatures of electronic devices, the term “significantly different,” when used to compare operating temperatures of two electronic devices, means and includes electronic devices operating respectively at temperatures differing by about 20% or more. Similarly, the comparative terms “relatively high temperature” versus “relatively low temperature” when applied to operating temperatures of two or more electronic devices in mutual operable communication for signal or power transmission, means and includes electronic devices operating respectively at temperatures differing by about 20% or more.

As used herein, the term “free space” means and includes a volume of space wherein only a gas or mixture of gases in vapor state, or a full or partial vacuum, resides. As used herein, the term “contained free space” means and includes a free space comprising a contained volume (e.g., a confined volume isolated from an ambient environment).

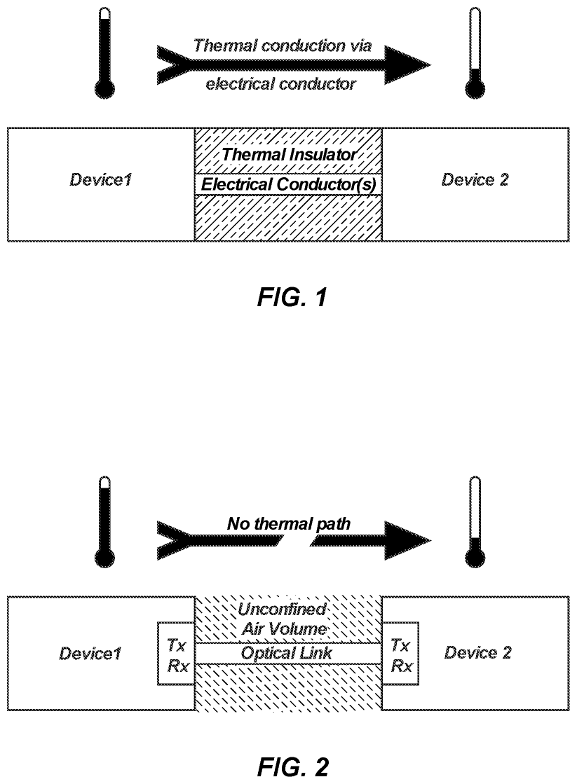

FIG. 1 schematically depicts a conventional technique for operably coupling two electronic devices operating at significantly different temperatures. As shown, relatively high temperature Device 1 is operably coupled to relatively low temperature Device 2 (the temperature disparity indicated by the thermometer graphics) by one or more conventional Electrical Conductors, for example metal (e.g., copper) wires. While a Thermal Insulator material is interposed between Device 1 and Device 2, a significant amount of heat is transferred from Device 1 to Device 2 through the electrical conductors.

FIG. 2 schematically depicts another conventional technique for operably coupling two electronic device operating at significantly different temperatures, wherein relatively high temperature Device 1 is operably coupled for signal transmission, to relatively low temperature Device 2 (the temperature disparity indicated by the thermometer graphics) via an Optical Link comprising an optical fiber extending between Transmitter/Receiver TxRx of Device 1 and Transmitter/Receiver TxRx, the Optical Link being far less conductive of heat than the conventional Electrical Conductors used in FIG. 1. As shown, there is also an unconfined Air Volume interposed between Device 1 and Device 2 to further inhibit heat transfer between the two Devices. Conventionally, Device 1 and Device 2 may be separated by substantial distances, on the order of meters to even kilometers, so heat transfer through an Optical Link is generally not problematic. However, as distances between operably coupled devices decreases to centimeters, millimeters or even shorter distances, such as between devices on a common printed circuit board (PCB) or other carrier substrate, heat transfer between devices operating at significantly different temperatures has become a significant issue. In addition, it is contemplated that, as device feature sizes further decrease and multiple devices at significantly different operating temperatures may be combined in three-dimensional assemblies, undesirable heat transfer may become ever-more significant.

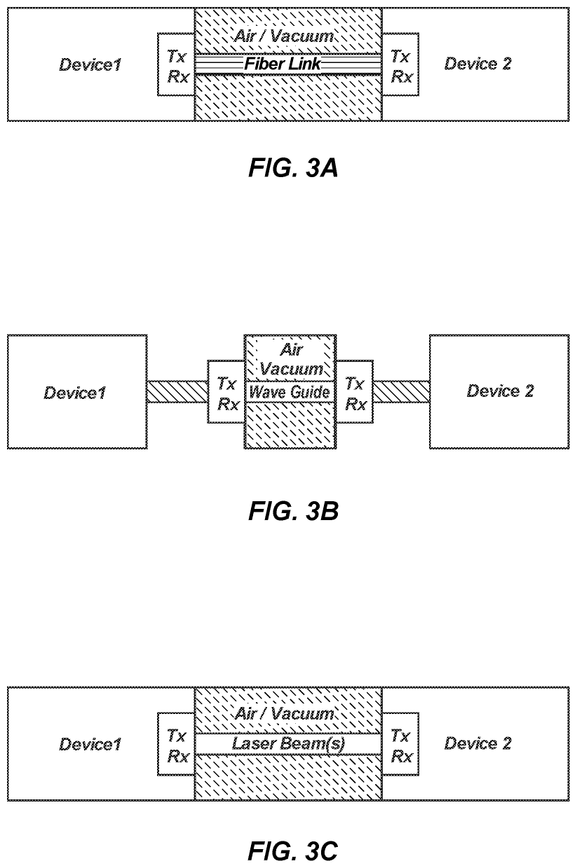

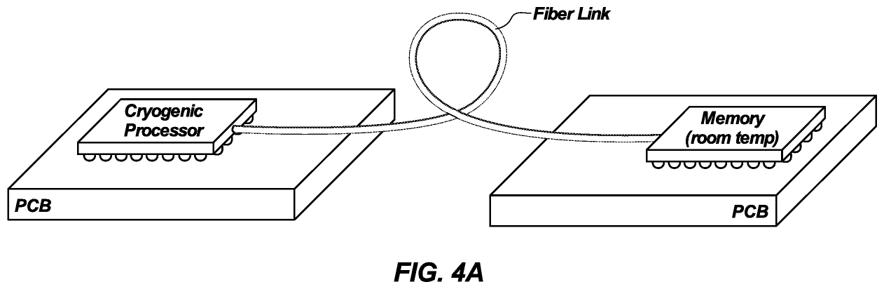

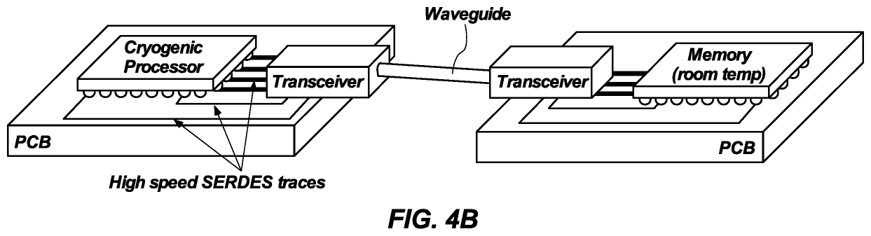

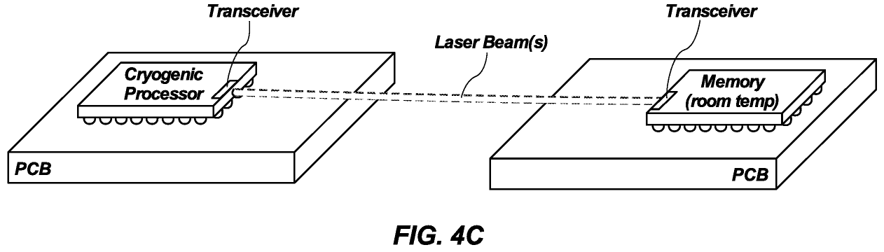

FIG. 3A schematically depicts an embodiment of the disclosure for operably coupling two electronic device operating at significantly different temperatures, wherein relatively high temperature Device 1 is operably coupled, at least for signal transmission, to relatively low temperature Device 2 via a Fiber Link (e.g., an optical fiber of a glass, for example silica glass, chalcogenide glass, fluorozirconate glass, or fluoroaluminate glass, or a ceramic or plastic) extending between Transmitter/Receiver TxRx of Device 1 and Transmitter/Receiver TxRx of Device 2, the Fiber Link being far less conductive of heat than the conventional Electrical Conductors used in FIG. 1. As shown, there is also ambient air or a full or partial Vacuum in a contained volume interposed between Device 1 and Device 2 and adjacent to (e.g., surrounding) the Fiber Link to further inhibit heat transfer between the two Devices. Notably, the arrangement of FIG. 3A does not require line of sight alignment of Device 1 with Device 2. It is also contemplated that, in lieu of a Fiber Link, a waveguide may be employed. A specific non-limiting example of a system implemented with a Fiber Link is depicted in FIG. 4A, wherein a Cryogenic Processor is in communication with Memory (e.g., DRAM) operating at room (i.e., controlled ambient or near-ambient) temperature through a Fiber Link, the contained ambient air or Vacuum volume of FIG. 3A not being depicted for clarity in FIG. 4A. As shown in FIG. 4A, each of the Cryogenic Processor and the Memory incorporates an integral Transceiver for emitting and receiving optical signals incorporated in laser beams.

FIG. 3B schematically depicts an embodiment of the disclosure for operably coupling two electronic device operating at significantly different temperatures, wherein relatively high temperature Device 1 is operably coupled, for signal transmission, power transmission, or both, to relatively low temperature Device 2 via a Waveguide for transmitting laser beams through the contained free space between Transmitter/Receiver TxRx of Device 1 and Transmitter/Receiver TxRx, the Waveguide being far less conductive of heat than the conventional Electrical Conductors used in FIG. 1 and even less conductive than the Fiber Link of FIG. 3A. As shown, there is also a Gap of Air or a full or partial Vacuum interposed in a contained volume between Device 1 and Device 2 adjacent (e.g., surrounding) the path of the Waveguide to further inhibit heat transfer between the two Devices. As shown, each of Device 1 or Device 2 may be remote from the Waveguide and may be in communication with its respective Transmitter/Receiver TxRx via one or more conventional electrical conductors or optical fibers. In such an arrangement, the free space across which the Waveguide extends need not be aligned with the locations of either Device. A specific, non-limiting example of a system implemented with a Waveguide according to FIG. 3B is depicted in FIG. 4B, wherein a Cryogenic Processor is in communication with Memory (e.g., DRAM) operating at room (i.e., controlled ambient or near-ambient) temperature through a Waveguide, the Air or Vacuum contained volume of FIG. 3B not being depicted for clarity in FIG. 4B. In FIG. 4B, communication between the Transceiver of each of the Cryogenic Processor and the Memory and that respective Device is depicted by way of example only as High speed SERDES traces.

FIG. 3C schematically depicts an embodiment of the disclosure for operably coupling two electronic device operating at significantly different temperatures, wherein relatively high temperature Device 1 is operably coupled, for signal transmission, power transmission, or both, to relatively low temperature Device 2 via one or more unconstrained Laser Beams (shown in broken lines) transmitted and received through the free space between Transmitter/Receiver TxRx of Device 1 and Transmitter/Receiver TxRx, the Laser Beams being far less conductive (e.g., substantially nonconductive) of heat than the conventional Electrical Conductors used in FIG. 1 and even less conductive than the Fiber Link of FIG. 3A or the Waveguide of FIG. 3B. As shown, there is also Air or a full or partial Vacuum interposed in the contained free space volume adjacent (e.g., through which the unconstrained Laser Beams transmit between Device 1 and Device 2 to further inhibit heat transfer between the two Devices. As shown, the Transmitter/Receiver TxRx of each of Device 1 or Device 2 may be integral with the respective Device and the Beams may be used to communicate across a relatively large free space wherein Device 1 and Device 2 are mutually aligned. A specific, non-limiting example of a implemented with one or more unconstrained Laser Beams according to FIG. 3C is depicted in FIG. 4C, wherein a Cryogenic Processor is in communication with Memory (e.g., DRAM) operating at room temperature through one or more Laser Beams (shown in broken lines), the Air or Vacuum contained volume of FIG. 3C not being depicted for clarity. Instead of the discrete Transceivers of FIG. 4B, however, the Cryogenic Processor and Memory may each be fabricated with an integral Transceiver as shown in FIG. 4C operably coupled to the circuitry of the respective device function within a semiconductor die configured for such function as shown in FIG. 4A, or in a Transceiver die assembled as part of a high bandwidth memory die stack including a controller (i.e., logic) die.

Laser generators employed for signal transfer may comprise, for example, an edge-emitting on-die laser, a vertical cavity surface emitting laser (VCSEL), a light emitting diode (LED) or injection laser diode (ILD) as an emitter to provide a light output signal at a preselected wavelength. A photodiode may be used as a receiver. By way of example, Time Division Multiplexing (TDM), Wavelength Division Multiplexing (WDM) or Frequency Division Multiplexing (FDM) may be used. Multiplexers and demultiplexers configured for signal conversion between optical and electrical may be used for optical data transmission and conversion of optical signals from and to electrical signals. In addition, data compression techniques may be employed to reduce the volume of data transmitted, the number of optical channels needed, or both. Laser generators employed for power transfer may comprise, for example, solid state laser generators operable to transmit close to the visible region of the electromagnetic spectrum (i.e., wavelengths of tens of micrometers to terns of nanometers) in combination with receivers comprising photoelectric cells. If an optical fiber is employed to transmit the laser beam for power transmission, such an approach is termed “power-over-fiber.” If the laser beam is transmitted through an optical fiber, a waveguide or an open gap between the devices, as described with respect to FIGS. 3A, 3B and 3C for either signal or power transmission, a lens may be employed to reduce the size of and focus the laser beam from the generator as described in U.S. Pat. No. 8,197,147, assigned to Edith Cowan University and Ytel Photonics Inc.

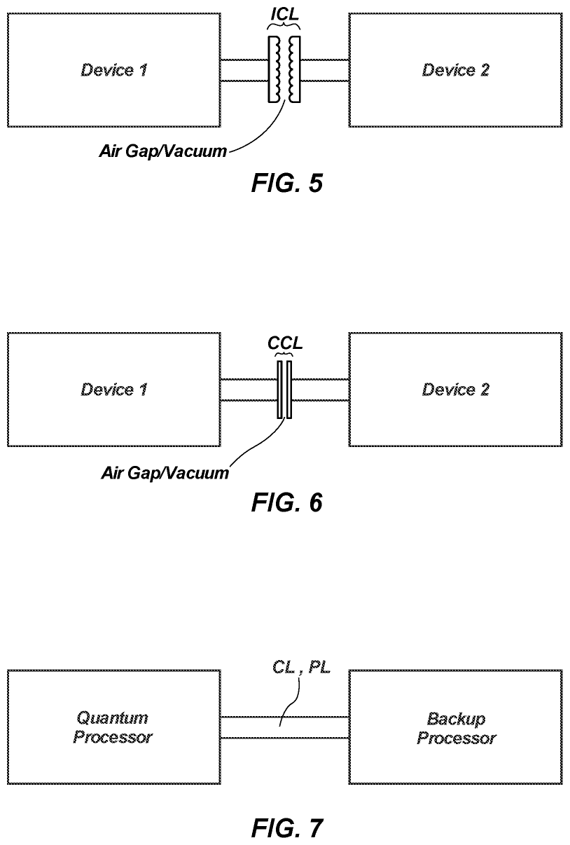

FIG. 5 schematically depicts an Inductive Coupling Link ICL between a relatively high temperature Device 1 and a relatively low temperature Device 2, Inductive Coupling Link ICL extending across and within a volume separating Device 1 and Device 2 comprising an Air Gap or a full or partial Vacuum. Inductive Coupling Link ICL employs a near-field technique, wherein power may be transferred over the volume separating Device 1 and Device 2 by magnetic fields. Similarly, an Inductive Coupling Link ICL may be employed to transmit signals between Device 1 and Device 2 using standard modulation schemes (e.g., amplitude modulation, phase modulation, frequency modulation) employed in radiofrequency communications.

FIG. 6 schematically depicts a Capacitive Coupling Link CCL between a relatively high temperature Device 1 and a relatively low temperature Device 2, Capacitive Coupling Link CCL extending across and within a volume separating Device 1 and Device 2 comprising an Air Gap or a full or partial Vacuum. A Capacitive Coupling Link CCL may be employed to transmit signals between Device 1 and Device 2 using DC-balanced signals with a zero DC component.

FIG. 7 schematically depicts an embodiment of the disclosure, wherein a Quantum Processor cooled by liquid Helium and operable at milliKelvin temperatures about 4K and below is in communication with a Backup Cryogenic Processor cooled by, for example, liquid Nitrogen at about 77K or solid CO₂ at about 196K and operable at a higher cryogenic temperature, which in turn is in communication with Memory operable at ambient or near-ambient temperatures. Communication links CL in accordance with the embodiments described in conjunction with any of FIGS. 3A, 3B, 3C, 5 or 6 may be employed between the various devices for signal transmission and, optionally, power transmission through a Power Link PL if power is routed through the Backup Processor or Quantum Processor.

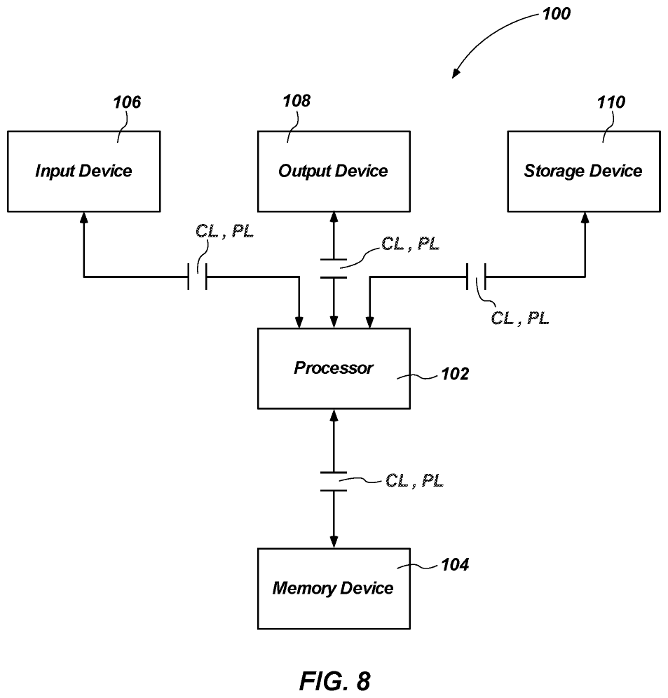

FIG. 8 schematically depicts an electronic system 100 comprising at least one cryogenic Processor 102, a Memory Device 104 operable at ambient or near-ambient temperatures, an Input Device 106 operable at ambient or near-ambient temperatures, an Output Device 108 operable at ambient or near-ambient temperatures, and a Storage Device 110 operable at ambient or near-ambient temperatures. The Memory Device may comprise, for example, DRAM, Fast Page Mode DRAM (FPM DRAM), extended data out DRAM (EDO DRAM), synchronous DRAM (SDRAM) including without limitation single data rate DRAM (SDR DRAM), double data rate DRAM (DDR DRAM), DDR2 SDRAM, DDR3 SDRAM, DDR4 SDRAM and DDR5 SDRAM. The Input Device 106 may comprise, for example, one or more of a mouse or other pointing device, a keyboard, a touchpad, a button, or a control panel. The Output Device 108 may comprise, for example, one or more of a monitor, a display, a printer, an audio output jack, a speaker, etc. In some embodiments, the Input Device 106 and the Output Device 108 may comprise a single touchscreen device that can be used both to input information to the electronic system 100 and to output visual information to a user. The Storage Device 110 may comprise one or more of magnetic storage (e.g., a hard drive) or optical storage (e.g., optical read\write discs), or Flash memory. The Input Device 106 and the Output Device 108 may communicate electrically with one or more of the memory device 104 and the cryogenic Processor 102. It is also contemplated that a primary, for example Quantum, cryogenic processor may be employed in electronic system 100 in communication with another, higher-temperature-operable backup cryogenic processor, as described in conjunction with FIG. 7, the latter processor in communication with Memory Device 104, Input Device 106, Output Device 108 and Storage Device 110. As shown, each of the devices is operably coupled to at least one other device in a heat-isolating manner by a Communications Link CL and, optionally, by a Power Link PL in accordance with embodiments of the disclosure.

In addition to the foregoing embodiments, it is contemplated for instances where power transmission via optical (i.e., laser) techniques or inductive coupling is unsuitable, that a power cable extending to a relatively low temperature (i.e., cryogenic) device may have an associated heat exchanger to reduce heat transfer from a power source operable at ambient or near-ambient temperatures to the relatively low temperature device.

In embodiments, an apparatus comprises a relatively high temperature electronic device, a relatively low temperature electronic device operably coupled to the relatively high temperature electronic device. The operable coupling comprises at least one of optical coupling, inductive coupling or capacitive coupling through at least one contained free space located between the electronic device and the other electronic device across one of air or a full or partial vacuum in a volume of the contained free space adjacent a path of the operable coupling. Related systems and methods are also disclosed.

In embodiments, an electronic system comprises at least one cryogenic processor, a memory device operable at ambient or near-ambient temperatures, an input device operable at ambient or near-ambient temperatures, and an output device operable at ambient or near-ambient temperatures. The at least one cryogenic processor is operably coupled to one or more of the memory device, the input device or the output device through a contained free space comprising air or a full or partial vacuum.

In embodiments, a method of operating an apparatus comprising at least a first device and a second device operable at a significantly different temperature than the first device comprises transmitting at least one of signals or power across a contained free space comprising one of air and a full or partial vacuum located between respective locations of the first device and the second device.

While certain illustrative embodiments have been described in connection with the figures, those of ordinary skill in the art will recognize and appreciate that embodiments encompassed by the disclosure are not limited to those embodiments explicitly shown and described herein. Rather, many additions, deletions, and modifications to the embodiments described herein may be made without departing from the scope of embodiments encompassed by the disclosure, such as those hereinafter claimed, including legal equivalents. In addition, features from one disclosed embodiment may be combined with features of another disclosed embodiment while still being encompassed within the scope of the disclosure.

What is claimed is:

1. An apparatus, comprising:
a relatively high temperature electronic device;
a relatively low temperature electronic device operably coupled to the relatively high temperature
electronic device; and
the operable coupling comprising at least one of optical coupling, inductive coupling or capacitive coupling through at least one contained free space between the electronic device and the other electronic device across one of air or a full or partial vacuum in a volume of the at least one contained free space adjacent a path of the operable coupling.

2. The apparatus of claim 1, wherein the relatively low temperature electronic device comprises a cryogenic processor, and the relatively high temperature device comprises one of an electronic device operable at ambient or near-ambient temperature, or another cryogenic processor operable at a significantly different temperature than an operating temperature of the cryogenic processor.

3. The apparatus of claim 2, wherein the electronic device operable at ambient or near-ambient temperature comprises a memory device, an input device, an output device, or a storage device.

4. The apparatus of claim 1, wherein the operable coupling comprises at least one of signal coupling and power coupling.

5. The apparatus of claim 1, wherein the operable coupling comprises optical coupling with one or more laser beams, and wherein each of the electronic device and the other electronic device has associated therewith either an optical transmitter, an optical receiver, or both, or an optical transceiver.

6. The apparatus of claim 5, wherein the optical transmitter, the optical receiver, or both, or the optical transceiver are integral with at least one of the electronic device and the other electronic device.

7. The apparatus of claim 1, wherein the optical coupling comprises at least one laser beam emitter associated with one of the electronic device and the other electronic device, and at least one optical receiver associated with another of the electronic device and the other electronic device.

8. An electronic system, comprising:
at least one cryogenic processor;
a memory device operable at ambient or near-ambient temperatures;
an input device operable at ambient or near-ambient temperatures;
an output device operable at ambient or near-ambient temperatures; and
wherein the at least one cryogenic processor is operably coupled to one or more of the memory device, the input device or the output device through a contained free space comprising air or a full or partial vacuum.

9. The electronic system of claim 8, wherein the at least one processor is operably coupled to each of the memory device, the input device and the output device through a contained free space comprising air or a full or partial vacuum.

10. The electronic system of claim 8, wherein the at least one cryogenic processor is operable at milliKelvin temperatures.

11. The electronic system of claim 8, wherein the operable coupling comprises at least one of optical coupling, inductive coupling or capacitive coupling.

12. The electronic system of claim 8, further comprising a storage device operable at ambient or near-ambient temperatures operably coupled to the at least one cryogenic processor operable at ambient or near-ambient temperatures.

13. The electronic system of claim 8, wherein the at least one cryogenic processor comprises two cryogenic processors operable at significantly different temperatures and mutually operably coupled through a contained free space comprising one of air or a full or partial vacuum.

14. The electronic system of claim 13, wherein one of the two cryogenic processors operable at a higher cryogenic temperature is operably coupled to one or more of the memory device, the input device and the output device through a contained free space comprising air or a full or partial vacuum.

15. The electronic system of claim 8, wherein the operable coupling comprises signal coupling, power coupling, or both.

16. The electronic system of claim 15, wherein the operable coupling comprises both signal coupling and power coupling, the signal coupling comprises optical coupling and the power coupling comprises inductive coupling.

17. A method of operating an apparatus comprising at least a first device and a second device operable at a significantly different temperature than the first device, the method comprising: transmitting at least one of signals or power across a contained free space comprising one of air and a full or partial vacuum located between respective locations of the first device and the second device.

18. The method of claim 17, further comprising transmitting the at least one of the signals or power across the contained free space using one or more of optical coupling, inductive coupling or capacitive coupling.

19. The method of claim 17, further comprising transmitting both signals and power across the contained free space.

20. The method of claim 17, further comprising selecting the first device to comprise a cryogenic processor and the second device to comprise memory operable at room temperature.

21. The method of claim 17, further comprising selecting the first device to comprise a cryogenic processor operable at milliKelvin temperatures and the second device to comprise a cryogenic processor operable at a significantly higher cryogenic temperature.

22. The method of claim 21, further comprising selecting a third device to comprise a memory device, and operably coupling the third device to the second device across a contained free space comprising one of air and a full or partial vacuum located between respective locations of the second device and the third device.
